(19) United States
(12) Patent Application Publication
(10) Pub. No.: US 2024/0258258 A1
(43) Pub. Date: Aug. 1, 2024

(54) SEMICONDUCTOR PACKAGE INCLUDING BALL GRID ARRAY CONNECTIONS WITH IMPROVED RELIABILITY

(71) Applicant: Taiwan Semiconductor Manufacturing Company, Hsinchu (TW)

(72) Inventors: Shih-Cheng Chang, Hsinchu (TW); Yao-Chun Chuang, Hsinchu (TW)

(21) Appl. No.: 18/103,698

(22) Filed: Jan. 31, 2023

(51) Int. Cl. H01L 23/00

(52) U.S. Cl. CPC H01L 24/11; H01L 24/10; H01L 24/13; H01L 24/14; H01L 24/16; H01L 24/81; H01L 2224/10126; H01L 2224/11011; H01L 2224/11334; H01L 2224/1182; H01L 2224/11849; H01L 2224/13082; H01L 2224/13111; H01L 2224/13139; H01L 2224/13147; H01L 2224/1357; H01L 2224/13644; H01L 2224/13655; H01L 2224/1369; H01L 2224/1413; H01L 2224/14505; H01L 2224/16145; H01L 2224/16227; H01L 2224/81191; H01L 2224/81192; H01L 2224/81201; H01L 2224/81815; H01L 2924/014; H01L 2924/20107

(57) ABSTRACT

A substrate or IC chip is connected with a second substrate or IC chip. This entails disposing electrically conductive balls on electrical bonding pads of a surface of the substrate or IC chip to form a ball grid array (BGA) disposed on the surface of the substrate or IC chip, and electrically and mechanically connecting the surface of the substrate or IC chip to the second substrate or IC chip using the BGA. An underfill material may be disposed on the surface of the substrate or IC chip around bonds between the balls and the electrical bonding pads. There may be at least two different types of electrically conductive balls in the BGA, such as solder balls and copper-based balls.

### BACKGROUND

The following relates to the semiconductor packaging arts, integrated circuit (IC) chip mounting arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, and 4 present a series of diagrammatic side-sectional views depicting steps in a method of reinforcing the bonds between electrically conductive balls of a ball grid array (BGA) and a substrate or integrated circuit (IC) chip.

FIG. 5 diagrammatically illustrates a diagrammatic plan view of the reinforced BGA produced by the method described with reference to FIGS. 1-4.

FIG. 6 diagrammatically illustrates a side-sectional view of the substrate or IC chip with a BGA reinforced by the method described with reference to FIGS. 1-4, electrically and mechanically connected by the BGA to a second substrate or IC chip.

FIGS. 7, 8, 9, and 10 diagrammatically illustrate side sectional views of a single electrically conductive ball of a BGA reinforced using the method described with reference to FIGS. 1-4, in which the electrically conductive ball is a pure copper or copper alloy ball (FIG. 7), a copper or copper alloy ball coated with a nickel film (FIG. 8), a copper or copper alloy ball coated with an organic solderability preservative (FIG. 9), or a copper or copper alloy core ball (FIG. 10).

FIG. 11 diagrammatically illustrates a plan view of a stencil used to align electrically conductive balls with bonding pads during ball drop placement of the balls to form a BGA.

FIG. 12 diagrammatically illustrates a plan view of the stencil of FIG. 11 with a stencil mask disposed on the stencil.

FIG. 13 diagrammatically illustrates a diagrammatic plan view of a BGA including two different types of electrically conductive balls.

FIGS. 14, 15, 16, 17, 18, and 19 present a series of diagrammatic side-sectional views depicting steps in a method of drop ball placement of electrically conductive balls of two different types to form the BGA of FIG. 13 with electrically conductive balls of two different types.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A wide range of semiconductor packages employ ball grid arrays (BGAs) for connecting two integrated circuit (IC) chips, or for connecting an IC chip to a substrate. For example, a BGA may be used to connect a dynamic random access memory (DRAM) chip to a logic IC chip. In another example, a chip-on-wafer (CoW) package may include an IC chip bonded to a substrate in the form of a silicon interposer with through-silicon vias (TSV's). The CoW package may in turn form a sub-package of a chip-on-wafer-on substrate (CoWoS) package in which the surface of the silicon interposer opposite that supporting the IC chip is bonded to a package substrate by a second BGA. These are merely nonlimiting illustrative examples.

However, BGAs can suffer from various reliability problems. One problem that can arise is that the bonds between electrically conductive balls of the BGA and the substrate or IC chip can break, leading to missing balls in the BGA. This can lead to higher-than-expected electrical resistance, or in extreme cases loss of electrical connectivity with a bonding pad that has too many or all of the electrically conductive balls bonding to that bonding pad missing. Breakage of a bond to an electrically conductive ball of the BGA can occur at various points in the packaging process, such as during thermal cycling, during board-level reliability (BLR) testing (e.g., during a drop BLR test), or so forth. Such ball bond breakage events are more likely as the size of the electrically conductive balls of the BGA decrease and/or ball density increases with the ongoing miniaturization of electronics for compact devices such as cellular telephones and other mobile electronics, for example.

Ball bond breakage is also more prevalent with copper-based BGA balls, such as bare copper or copper alloy balls, or copper-core balls with a core of copper or copper alloy coated with a solder coating. Copper-based balls facilitate achieving high electrical current density due to the higher electrical conductivity of copper compared with typical solders used for solder-based electrically conductive balls of BGAs, such as commercial SAC405 or SAC3054 lead-free solder balls. The higher prevalence of ball bond breakage with copper-based balls can be overcome by replacing them with solder balls, but at the cost of a higher ball count and consequently larger semiconductor package size. The larger package size in turn reduces or eliminates the benefit of higher density integrated circuitry with smaller critical dimension.

Approaches disclosed herein remediate these and other problems.

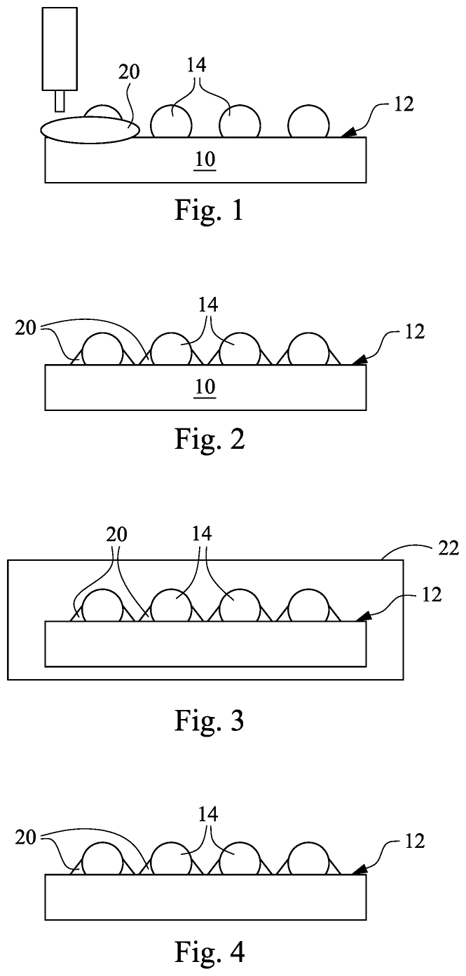

With reference to FIGS. 1-10, in one approach the problem of ball bond breakage is remediated by improving the robustness of the bond through the use of an underfill material that is disposed on the surface of the substrate or IC chip around bonds between the electrically conductive balls and the electrical bonding pads. The underfill material is dispensed and cured before electrically and mechanically connecting the surface of the substrate or IC chip to a second substrate or IC chip using the BGA disposed on the surface of the substrate or IC chip. In this way, the bonds between the electrically conductive balls and the surface of the substrate or IC chip are strengthened before commencing with the attachment process. This provides greater protection against missing balls compared with an approach in which underfill material is injected between the substrate or IC chip and the second substrate and IC chip after the attachment.

However, dispensing and curing the underfill material before attachment to the second substrate or IC chip presents certain difficulties. The underfill material should be electrically insulating. But if the electrically insulating underfill material covers the electrically conductive balls of the BGA, then the underfill material will hinder or prevent the balls from forming electrical connections with the second substrate or IC chip. On the other hand, if the layer of underfill material is too thin it might not be expected to provide an effective amount of structural reinforcement for the ball bonds.

As disclosed herein, however, if the underfill material comprises a liquid epoxy or plastic molding compound that is dispensed on the surface of the substrate or IC chip, then it will move by capillary action to aggregate around the bonds of the electrically conductive balls to the surface so as to form annuluses of underfill material around the balls. This provides the desired structure reinforcement for the ball bonds while employing a limited amount of underfill material and avoiding the potential problem of covering the electrically conductive balls and thereby preventing electrical contact during the attachment process using the BGA.

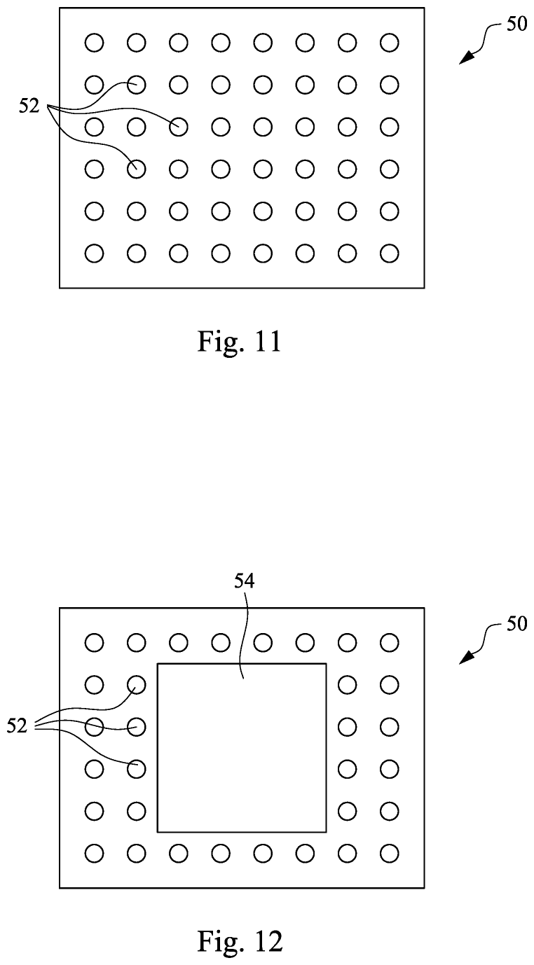

With reference to FIGS. 11-19, in another aspect disclosed herein for improving robustness of BGA arrays, an approach is disclosed by which two (or more) different types of electrically conductive balls can be used in a single BGA array. For example, the electrically conductive balls that make connection to electrical bonding pads for electrical power (for example, VDD and VSS pads of a CMOS logic IC chip) can be copper-based balls with high electrical conductivity, while the electrically conductive balls that make connection to electrical bonding pads for signals or other lower power can be solder balls. In some such embodiments, the copper-based balls are disposed in a central region of the surface of the substrate or IC chip, and the solder balls are disposed in a peripheral region surrounding the central region. This arrangement places the solder balls, which are less prone to ball bond breakage, in the peripheral regions that generally experience greater stress than the central region.

It will be appreciated that these aspects can be usefully combined, for example as a BGA made up of both copper-based balls and solder balls, whose ball-surface bonds are further reinforced by underfill material.

With reference to FIGS. 1-4, a method for disposing an underfill material on the surface of the substrate or IC chip around bonds between the electrically conductive balls and the electrical bonding pads is described. In FIG. 1, a substrate or IC chip 10 has a surface 12 that includes electrical bonding pads (not shown in FIGS. 1-4), and an array of electrically conductive balls 14 making up a BGA disposed on the on the surface 12 (and more particularly on electrical bonding pads of the surface 12). By way of nonlimiting illustrative example, the substrate or IC chip 10 may be a DRAM chip, a logic IC chip, a silicon interposer with TSV's, or so forth. In embodiments in which the substrate or IC 10 is an IC chip, it may include transistors (e.g. CMOS devices) and other electronic devices, and one or (typically) more metallization layers, the topmost layer of which includes vias connecting to electrical bonding pads on the surface 12. The surface 12 is a planar surface having a set of electrical bonding pads for electrically connecting with the electronic devices of the IC chip to power these devices, inject and/or extract signals from these devices, and/or so forth. In the case in which the substrate or IC chip 10 is a substrate such as a silicon interposer, the electrical bonding pads typically connect with TSV's of the interposer. These are merely some nonlimiting illustrative examples of possible embodiments of the substrate or IC chip 10. The electrically conductive balls 14 are bonded to the electrical bonding pads of the surface 12 of the substrate or IC chip 10 in any suitable manner. In some embodiments, the electrical bonding pads (also sometimes called under-bum metallization, or UBM) are coated with a thin film metal layer stack to facilitate bonding of the electrically conductive balls 14. If the electrically conductive balls 14 are solder balls or solder-coated balls, then the solder of the balls can be suitably heated to solder-bond the balls 14 to the surface 12. If the electrically conductive balls 14 are bare copper or copper alloy balls then a separate solder material can be used for the bonding.

With continuing reference to FIGS. 1-4, after the electrically conductive balls 14 are bonded to the surface 12 of the substrate or IC chip 10, the underfill material comprising a liquid epoxy or plastic molding compound 20 is dispensed on the surface 12 of the substrate or IC chip 10, as shown in FIG. 1. As further shown in FIG. 2, the underfill material 20 dispensed onto the surface 12 of the substrate or IC chip 10 collects around the bonds between the electrically conductive balls 14 and the electrical bonding pads by capillary action, leading to the formation of annuluses of the underfill material 20 around the respective electrically conductive balls 14. With reference to FIG. 3, after the dispensing, the liquid epoxy or plastic molding compound 20 is cured in an oven 22 to solidify the liquid epoxy or plastic molding compound. The curing time and temperature depends on the particular type of underfill material 20 and in some cases secondarily on the amount of underfill material that is dispensed. In one nonlimiting illustrative embodiment, the curing is done at 150° C. for 30 minutes. After the curing, the substrate or IC chip 10, as shown in FIG. 4.

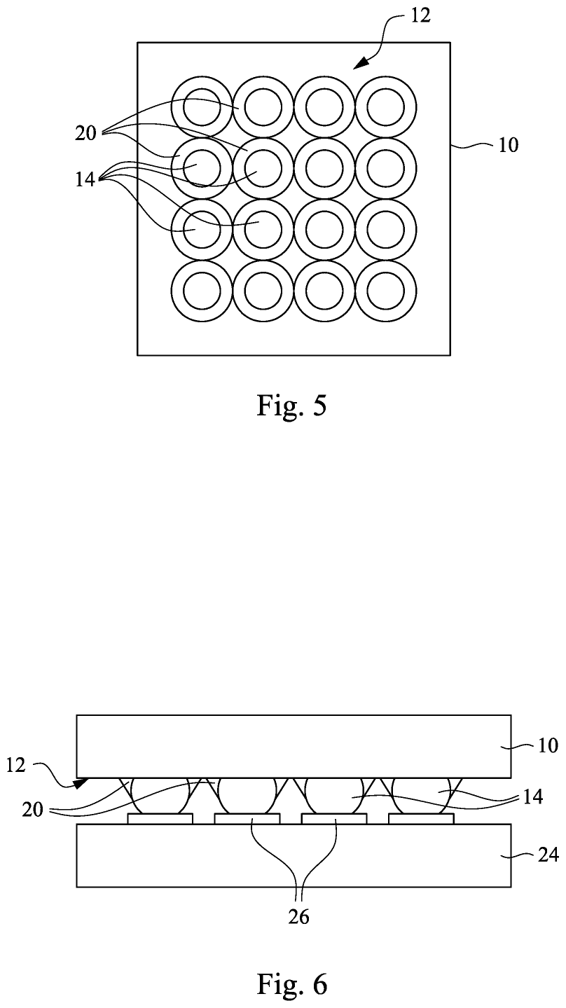

With reference to FIG. 5, a plan view of the surface 12 of the substrate or IC chip 10 is diagrammatically shown after the dispensing and curing of the underfill material 20. As seen in FIG. 5, the underfill material 20 collects around the bonds between the electrically conductive balls 14 and the electrical bonding pads by capillary action, leading to the formation of annuluses of the underfill material 20 around the respective electrically conductive balls 14. The annuluses of underfill material 20 around electrically conductive balls 14 may be separate from one another, or the annuluses of underfill material 20 around neighboring electrically conductive balls 14 may touch or slightly overlap, as shown in FIG. 5. As seen in the plan view of FIG. 5, the electrically conductive balls 14 form a ball grid array (BGA) disposed on the surface 12 of the substrate or IC chip 10. In the diagrammatic illustrative example of FIG. 5, the BGA consists of a 4×4 rectilinear array of 16 electrically conductive balls 14, each surrounded by an annulus of underfill material 20. However, more generally the electrically conductive balls of the BGA are distributed on electrical bonding pads of the surface 12 of the substrate or IC chip 10, and these bonding pads may be variously distributed. Hence, more typically the BGA will not be rectilinear but rather can have various and often nonuniform distributions of electrically conductive balls. Moreover, it will be appreciated that the BGA for a practical electronic device will usually consist of many more than 16 balls, e.g. it may include hundreds, thousands, or more electrically conductive balls distributed over the surface 12 of the substrate or IC chip 10.

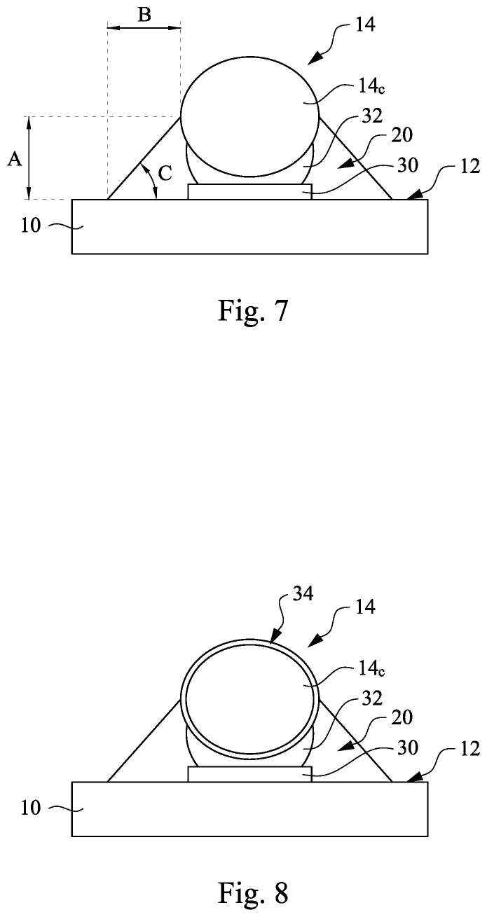

With reference to FIG. 6, after the process of FIGS. 1-4 is complete, the surface 12 of the substrate or IC chip 10 is electrically and mechanically connected to a second substrate or IC chip 24 using the BGA disposed on the surface 12 of the substrate or IC chip 10. This bonding process may, for example, employ temperature to partially melt solder of the balls 14 or solder pre-dispensed on the second substrate or IC chip 24, and/or may employ applied pressure. The connecting of the substrate or IC chip 10 and the second substrate or IC chip 24 via the BGA provides mechanical connection since the balls are already bonded to the surface 12 of the substrate or IC chip 10, and are additionally bonded to the second substrate or IC chip 24 during the connecting process. The connecting process also provides electrical connection between the substrate or IC chip 10 and the second substrate or IC chip 24 via the BGA because the balls 14 are electrically conductive and are bonded to electrical bonding pads 26 of the second substrate or IC chip 24 that are arranged to coincide with the electrically conductive balls 14 of the BGA. In the illustrative connecting process of FIG. 6, the substrate or IC chip 10 is inverted and placed on top of the second substrate or IC chip 24; however, in an alternative embodiment the substrate or IC chip 10 may be oriented as shown in FIG. 4 and the second substrate or IC chip 24 may be instead inverted and placed on top of the substrate or IC chip 10.

It should be noted that the electrically conductive balls 14 are not necessarily perfectly spherical in shape. Moreover, the electrically conductive balls 14 may deform significantly during the electrical and mechanical connecting process shown in and described with reference to FIG. 6. The term “electrically conductive ball” as used herein is does not imply a spherical shape of the electrically conductive balls 14, and the term “electrically conductive ball” is used herein to refer to the electrically conductive balls 14 even after potentially significant shape deformation during the bonding process, for example as shown in FIG. 6. However, the electrically conductive ball 14 is typically at least approximately spherical in shape prior to its use in attachment to the second substrate or IC chip 24, for example with a diameter of 100 micron to 800 micron in some nonlimiting illustrative examples.

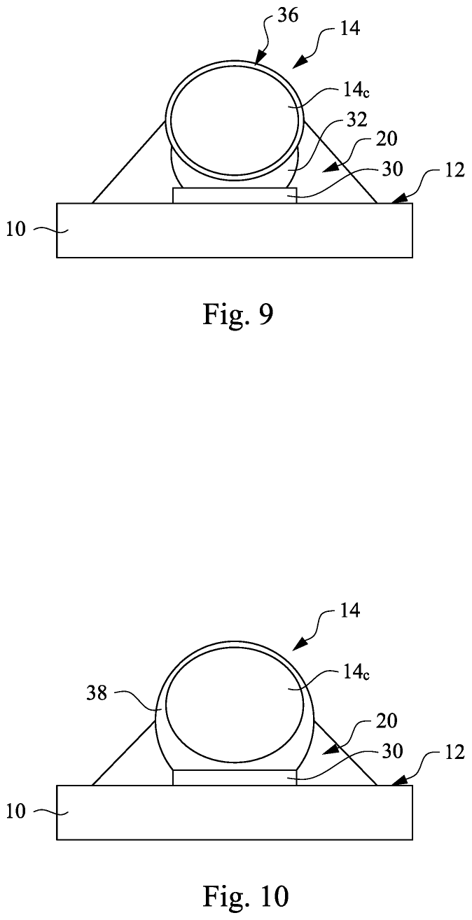

With reference now to FIG. 7, a side sectional view passing through one electrically conductive ball 14 bonded to the surface 12 of the substrate or IC chip 10 is shown, with a corresponding annulus of underfill material 20 encircling the bond between the electrically conductive ball 14 and an electrical bonding pad 30 of the surface 12 of the substrate or IC chip 10 to which the electrically conductive ball 14 is bonded. As diagrammatically shown in FIG. 7, the collection of the underfill material 20 around the bond between the electrically conductive ball 14 and the electrical bonding pad 30 by capillary action naturally tends to cause the resulting annulus of underfill material 14 to ramp upward toward the electrically conductive ball 14, so that the underfill material is thickest (i.e., has greatest height, denoted in FIG. 7 as height A) where it contacts the electrically conductive ball 14, and slopes away from the ball 14. The maximum height A of the annulus of underfill material 20 (as measured from the surface 12 of the substrate or IC chip 10) should be less than the diameter (here corresponding to the height) of the electrically conductive ball 14, so as to ensure the underfill material 20 does not completely cover the electrically conductive ball 14. This ensures that at least a portion of the electrically conductive ball 14 is exposed so as to be bonded to the second substrate or IC chip 24 in the connection operation shown in FIG. 6. As there may be some statistical variation between the heights A of the annuluses of underfill material around the respective electrically conductive balls 14 and as furthermore the diameters of the balls 14 themselves may have some statistical variance, in some embodiments the annuluses of underfill material 20 have heights in a range of 20% and 90% of a diameter of the electrically conductive balls. The lower bound of around 20% for these embodiments ensures that there is enough underfill material contacting the region of the bond between the electrically conductive ball 14 and an electrical bonding pad 30 of the surface 12 of the substrate or IC chip 10 to ensure the underfill material 20 can provide adequate structural reinforcement for that bond.

With continuing reference to FIG. 7, the effect of the capillary action-driven collection of the underfill material into the annulus of underfill material 20 produces the sloping of the underfill material away from the electrically conductive ball 14 with increasing distance from the ball 14. In some nonlimiting embodiments, the annuluses of the underfill material 20 extend away from the respective ball bonds along the surface of the substrate or IC chip 10 a distance B that is in a range of 20% and 90% of a diameter of the electrically conductive ball. This range, coupled with the range of the height A of the annulus of underfill material 20, again provides sufficient underfill material to provide the desired bond structural reinforcement. The sloping sidewall of the annulus in the example of FIG. 7 forms an angle C which may in some nonlimiting embodiments be in a range of 30 degrees to 80 degrees. However, it is noted that while the illustrative example of FIG. 7 shows a linearly slanted sidewall, the sidewall could be curved with a concave or convex shape.

In the embodiment of FIG. 7, the electrically conductive ball 14 consists of a bare copper or copper alloy ball 14c. To enable the bonding of this bare copper or copper alloy ball 14c to the electrical bonding pad 30 of the surface 12 of the substrate or IC chip 10, solder material 32 is applied at the interface therebetween. For example, the solder material 32 could be applied to the electrical bonding pad 30 prior to the electrically conductive ball 14 being placed onto it.

With reference to FIGS. 8-10, the disclosed approach of reinforcing the bond of the electrically conductive ball 14 to the electrical bonding pad 30 of the surface 12 of the substrate or IC chip 10 with the annulus of underfill material 20 can be utilized in conjunction with other types of electrically conductive balls. FIG. 8 illustrates an example in which the bare copper or copper alloy ball of FIG. 7 is replaced by a copper or copper alloy ball 14c coated with a film 34 of nickel, gold, or another highly electrically conductive material. FIG. 9 illustrates an example in which the bare copper or copper alloy ball of FIG. 7 is replaced by a copper or copper alloy ball 14c coated with an organic solderability preservative 36, such as a rosin, resin, azole, various combinations thereof, or so forth. FIG. 10 illustrates an example in which the electrically conductive ball 14 is a copper or copper alloy ball 14c coated with a coating of a solder material 38, sometimes referred to in the art as a copper-core ball. The embodiment of FIG. 10 advantageously avoids the step of initially applying the separate solder 32 as in the example of FIG. 7, since the solder coating 38 provides the solder for forming the bond. It will be appreciated that FIGS. 7-10 merely present some nonlimiting illustrative examples of some possible configurations of the electrically conductive balls 14.

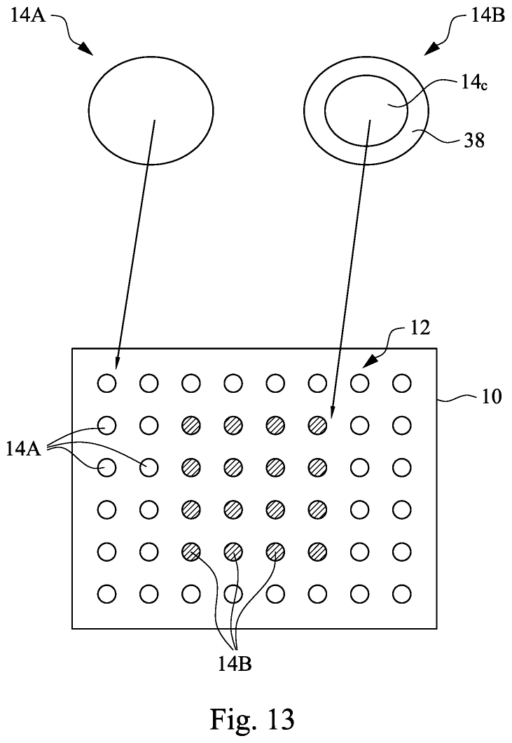

With reference now to FIGS. 11-19, in another aspect disclosed herein for improving robustness of BGA arrays, an approach is disclosed by which two (or more) different types of electrically conductive balls can be used in a single BGA array. FIG. 11 illustrates a stencil 50 having through-holes 52 for guiding placement of the electrically conductive balls 14. The through-holes 52 are sized to receive the electrically conductive balls 14, and are aligned with the electrical bonding pads 30 of the surface 12 of the substrate or IC chip 10. FIG. 12 illustrates the stencil 10 with a stencil mask 54 disposed on the stencil 50.

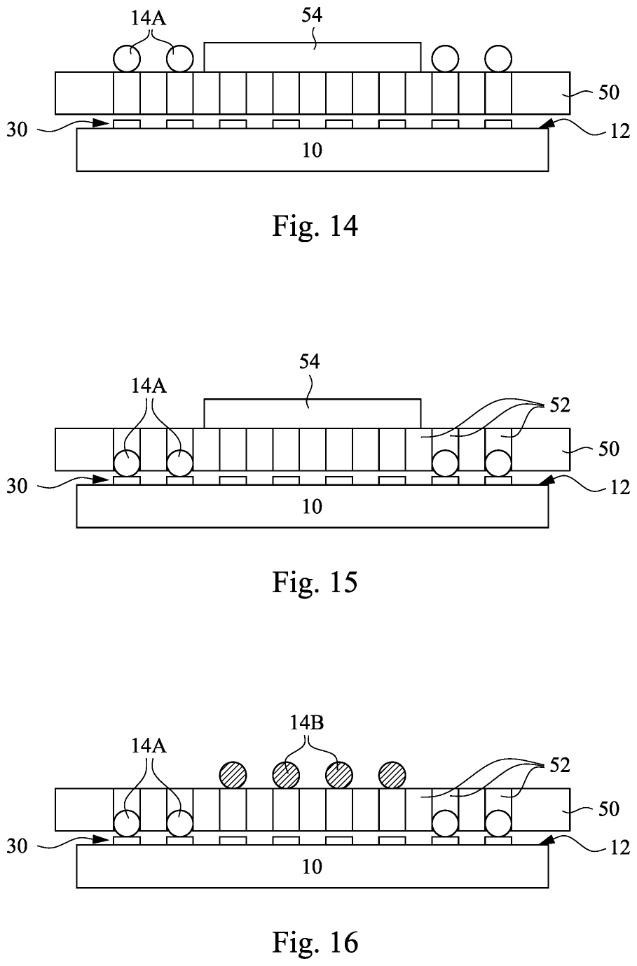

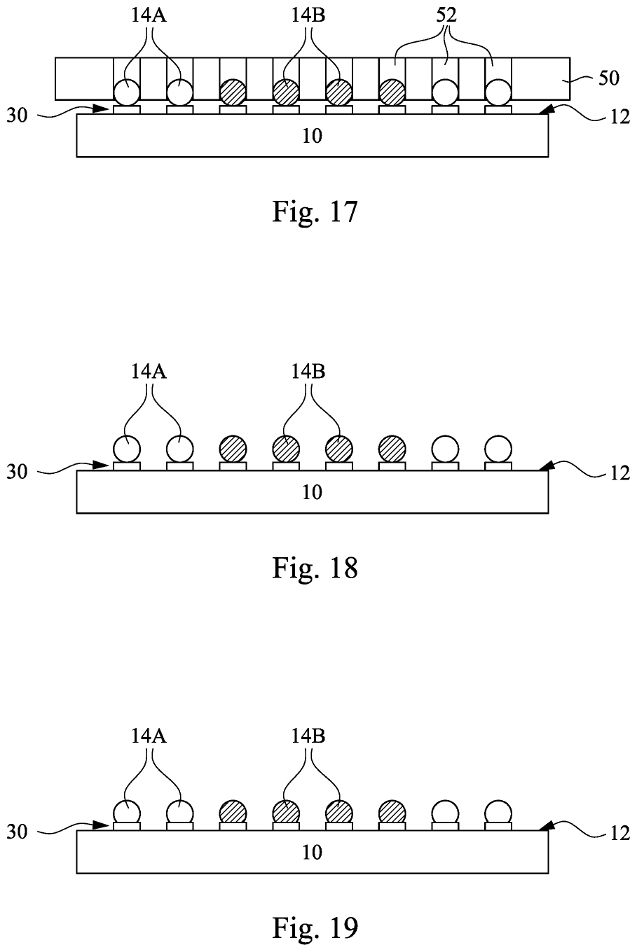

With reference to FIG. 13, a BGA is shown which includes two different types of electrically conductive balls disposed on the surface 12 of the substrate or IC chip 10, namely electrically conductive balls 14A and electrically conductive balls 14B. In the illustrative example of FIG. 13, the electrically conductive solder balls 14A are solder balls, such as for example, SAC405 solder balls or SAC305 solder balls. The illustrative electrically conductive balls 14B are copper-based electrically conductive balls, and more particularly are copper-core balls of the type shown in FIG. 10 which include the copper or copper alloy ball 14c coated with the coating of solder material 38. It will be noted that in the BGA of FIG. 13, the solder balls 14A are aligned with the through-holes 52 which are in peripheral region of the stencil 50 that is not covered by the stencil mask 54 in FIGS. 12, and the copper-based electrically conductive balls 14B are aligned with the through-holes 52 which are in the central region of the stencil 50 that is covered by the stencil mask 54 in FIG. 12. The use of the stencil 50 and stencil mask 54 in manufacturing the BGA of FIG. 13 is next described with reference to FIGS. 14-19.

FIG. 14 shows a side sectional view of the substrate or IC chip 10 with the electrical bonding pads 30 of the surface 12 shown, and with the stencil 50 disposed on the surface 12 of the substrate or IC chip 10 with the through-holes 52 aligned with the electrical bonding pads 30. As further seen in FIG. 14, the stencil mask 54 is disposed on the stencil 50, and in the lateral directions is arranged as shown by the plan view of FIG. 12. As further seen in FIG. 14, the solder balls 14A are in position to be inserted into the through-holes of the peripheral region of the stencil 50 that are not covered by the stencil mask 54. However, the stencil mask positioned as shown in the plan and side-sectional views of respective FIGS. 12 and 14 prevents the solder balls from being inserted into the through-holes underneath the stencil mask 54.

FIG. 15 shows the same configuration as FIG. 14, except that in FIG. 15 the solder balls 14A have now been inserted through the through-holes 52 not covered by the stencil mask 54 so they are positioned on electrical bonding pads 30 of the surface 12 of the substrate or IC device 10.

FIG. 16 shows the configuration of FIG. 15 after removal of the stencil mask 54 and placement of the copper-based electrically conductive balls 14B over through-holes 52 in the central region of the stencil 50 which are now uncovered by the removal of the stencil mask 54.

FIG. 17 shows the same configuration as that of FIG. 16, except that in FIG. 17 the copper-based electrically insulating balls 14B have now been inserted through the through-holes 52 in the central region so they are positioned on electrical bonding pads 30 of the surface 12 of the substrate or IC device 10.

FIG. 18 shows the substrate or IC device 10 after the stencil 50 has been removed from the surface 12 of the substrate or IC device 10. Both the solder balls 14A and the copper-based electrically conductive balls 14B remain in place on electrical bonding pads 30 of the surface 12 of the substrate or IC device 10. At this point, a reflow process is suitably performed to cause the solder of the solder balls 14A and the solder material coating 38 of the copper-core balls 14B to reflow to form bonds connecting the electrically conductive balls 14A and 14B to the electrical bonding pads 30 of the surface 12 of the substrate or IC device 10. The choice of temperature for the reflow process is made based on the type of solder and other factors such as the size of the balls. In one nonlimiting illustrative example, the reflow is done at 260° C.

FIG. 19 shows the substrate or IC device 10 after the reflow process is complete. As seen, the solder of the balls 14A and 14B has reflowed to form the bonds. FIG. 19 can also be recognized as a side sectional view of the substrate or IC device 10 shown in FIG. 13.

The method of FIGS. 14-19 employ a single stencil mask 54. This is suitable if in the operation depicted in FIG. 16 the presence of the solder balls 14A in the through-holes of the peripheral region is sufficient to prevent the copper-core balls 14B from entering those through-holes. In other words, if the depth of the through-holes is not too much larger than the diameter of the solder balls 14A then it will not be possible for those through-holes to be “double-loaded”. However, if this is not the case, then the operation shown in FIG. 16 could employ a second stencil mask (not shown), this one covering the peripheral region of the stencil 50 where the solder balls 14A are to go. This second stencil mask would ensure that the copper-core solder balls 14B cannot enter the through-holes of the peripheral region. Still further, multiple stencil masks could be employed to place three (or even more) different types of electrically conductive balls at individually targeted regions, so that the BGA could have three (or even more) different types of electrically conductive balls.

With reference particularly now to FIG. 13 showing the plan view of the BGA including the two different types of electrically conductive balls 14A and 14B, having different types of balls in a single BGA can have certain advantages. As previously noted, the solder balls 14A tend to be less prone to bond breakage and consequent missing balls as compared with copper-based balls 14B. However, the copper-based balls 14B have higher electrical conductivity than the solder balls 14A, and hence the copper-based balls 14B are beneficially used for contacting electrical bond pads on the surface 12 of the substrate or IC chip 10 that will be carrying high electrical current. Hence, in the BGA of FIG. 13, the copper-based balls 14B can be used to provide electrical contact with electrical bonding pads 30 for higher-electrical current tasks such as providing VDD and VSS power. The solder balls 14A can be used to provide electrical contact with electrical bonding pads 30 for lower electrical current tasks such as import and export of electrical signals. In such a BGA with both solder balls 14A and copper-based balls 14B, the solder balls 14A provide more robust bond strength and reliability, and hence can compensate for the less robust bond strength and reliability of the copper-based balls 14B in the BGA combining both types.

To further leverage the more robust bond strength and reliability of the solder balls 14A in such an array, if the fanout of the electrical bonding pads 30 of the surface 12 of the substrate or IC chip 10 is sufficiently flexible then those bonding pads 30 that are expected to carry higher electrical current (e.g. VDD and VSS pads) and which therefore will be populated with copper-based balls 14B can be placed in the central region of the BGA, as shown in FIG. 13; whereas, those bonding pads 30 that are expected to carry lower electrical current (e.g. signal pads) and which therefore will be populated with solder balls 14A can be placed in the peripheral region of the BGA, as further shown in FIG. 13. Since the peripheral region of the substrates or IC chips 10 and 24 connected by the BGA (see FIG. 6 and related discussion) can be expected to experience larger forces than the central region, this placement advantageously puts the solder balls 14A with their more robust bonds in those peripheral regions and puts the copper-based balls with their less robust bonds in the more protected central region.

As a further note, it will be appreciated that the ball stabilization by underfill material 20 previously described with reference to FIGS. 1-10 can optionally be employed with the substrate or IC device 10 of FIGS. 13 and 19 whose BGA has two (or more) different types of electrically conductive balls 14A and 14B. That is, the substrate or IC device 10 of FIGS. 13 and 19 whose BGA has two different types of electrically conductive balls (solder balls 14A and copper-core balls 14B) can be subsequently processed by the method described with FIGS. 1-4 to add the annuluses of underfill material 20 around both the solder balls 14A and the copper-core balls 14B to synergistically combine the improved stability provided by the underfill 20 with the improved stability provided by using the solder balls 14A in areas that do not call for conducting high electrical current levels.

In the following, some further embodiments are described.

In a nonlimiting illustrative embodiment, a method is disclosed of connecting a substrate or IC chip and a second substrate or IC chip. The method includes disposing electrically conductive balls on electrical bonding pads of a surface of the substrate or IC chip to form a BGA disposed on the surface of the substrate or IC chip, and electrically and mechanically connecting the surface of the substrate or IC chip to the second substrate or IC chip using the BGA disposed on the surface of the substrate or IC chip. In this method, the disposing of the electrically conductive balls on the electrical bonding pads of the surface of the substrate or IC chip to form the BGA includes at least one of: (i) bonding the electrically conductive balls to the electrical bonding pads of the surface of the substrate or IC chip and disposing an underfill material on the surface of the substrate or IC chip around bonds between the electrically conductive balls and the electrical bonding pads; and/or (ii) disposing the electrically conductive balls of at least two different types on the electrical bonding pads of the surface of the substrate or IC chip to form the BGA comprising the electrically conductive balls of the at least two different types disposed on the surface of the substrate or IC chip.

In a nonlimiting illustrative embodiment, a semiconductor package includes: a substrate or IC chip having electrical bonding pads disposed on a surface of the substrate or IC chip; a second substrate or IC chip; and a BGA electrically and mechanically connecting the surface of the substrate or IC chip to the second substrate or IC chip. The BGA includes electrically conductive balls bonded to the electrical bonding pads of the surface of the substrate or IC chip and to the second substrate or IC chip, and underfill material disposed on the surface of the substrate or IC chip around bonds between the electrically conductive balls and the electrical bonding pads of the surface of the substrate or IC chip.

In a nonlimiting illustrative embodiment, a semiconductor package includes: a substrate or IC chip having electrical bonding pads disposed on a surface of the substrate or IC chip; a second substrate or IC chip; and a BGA electrically and mechanically connecting the surface of the substrate or IC chip to the second substrate or IC chip. The BGA includes electrically conductive balls of at least two different types.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of connecting a substrate or integrated circuit (IC) chip and a second substrate or IC chip, the method comprising:
disposing electrically conductive balls on electrical bonding pads of a surface of the substrate or IC chip to form a ball grid array (BGA) disposed on the surface of the substrate or IC chip; and
electrically and mechanically connecting the surface of the substrate or IC chip to the second substrate or IC chip using the BGA disposed on the surface of the substrate or IC chip;
wherein the disposing of the electrically conductive balls on the electrical bonding pads of the surface of the substrate or IC chip to form the BGA includes at least one of:
bonding the electrically conductive balls to the electrical bonding pads of the surface of the substrate or IC chip and disposing an underfill material on the surface of the substrate or IC chip around bonds between the electrically conductive balls and the electrical bonding pads; and/or
disposing the electrically conductive balls of at least two different types on the electrical bonding pads of the surface of the substrate or IC chip to form the BGA comprising the electrically conductive balls of the at least two different types disposed on the surface of the substrate or IC chip.

2. The method of claim 1 wherein the disposing of the electrically conductive balls on the electrical bonding pads of the surface of the substrate or IC chip to form the BGA includes:
bonding the electrically conductive balls to the electrical bonding pads of the surface of the substrate or IC chip; and
disposing the underfill material on the surface of the substrate or IC chip around bonds between the electrically conductive balls and the electrical bonding pads.

3. The method of claim 2 wherein the disposing of the underfill includes:
after the bonding, dispensing the underfill material comprising a liquid epoxy or plastic molding compound on the surface of the substrate or IC chip, wherein the underfill material collects around the bonds between the electrically conductive balls and the electrical bonding pads by capillary action; and
after the dispensing, curing the liquid epoxy or plastic molding compound to solidify the liquid epoxy or plastic molding compound.

4. The method of claim 2 wherein the disposing of the electrically conductive balls on the electrical bonding pads of the surface of the substrate or IC chip to form the BGA includes:
disposing a first type of electrically conductive ball comprising a solder ball without a core of copper or copper alloy in a peripheral region of the surface of the substrate or IC chip; and
disposing a second type of electrically conductive ball consisting of a copper or copper alloy or comprising a core of copper or copper alloy coated with a coating in a central region of the surface of the substrate or IC chip that is surrounded by the peripheral region.

5. The method of claim 2 wherein the underfill material disposed around the bonds between the electrically conductive balls and the electrical bonding pads form annuluses of the underfill material encircling the respective bonds.

6. The method of claim 5 wherein the annuluses of the underfill material do not completely cover the respective electrically conductive balls.

7. The method of claim 5 wherein the annuluses of the underfill material have heights in a range of 20% and 90% of a diameter of the electrically conductive balls.

8. The method of claim 5 wherein the annuluses of the underfill material extend away from the respective bonds along the surface of the substrate or IC chip a distance that is in a range of 20% and 90% of a diameter of the electrically conductive ball.

9. The method of claim 1 wherein the disposing of the electrically conductive balls on the electrical bonding pads of the surface of the substrate or IC chip to form the BGA includes:
disposing the electrically conductive balls of at least two different types on the electrical bonding pads of the surface of the substrate or IC chip to form the BGA comprising the electrically conductive balls of the at least two different types disposed on the surface of the substrate or IC chip.

10. The method of claim 9 wherein the electrically conductive balls of at least two different types include:
a first type of electrically conductive ball comprising a solder ball without a core of copper or copper alloy; and
a second type of electrically conductive ball consisting of a copper or copper alloy or comprising a core of copper or copper alloy coated with a coating.

11. The method of claim 9 wherein the electrically conductive balls of at least two different types include the electrically conductive balls of a first type and electrically conductive balls of a second type that is different from the first type, and the disposing of the electrically conductive balls of at least two different types on the electrical bonding pads of the surface of the substrate or IC chip includes:
disposing a stencil on the surface of the substrate or IC chip, the surface having through-holes sized to receive the electrically conductive balls and aligned with the electrical bonding pads of the surface of the substrate or IC chip;
disposing a stencil mask on the stencil;
with the stencil mask disposed on the stencil, disposing electrically conductive balls of the first type into through-holes of the stencil that are not covered by the stencil mask;
after the disposing of the electrically conductive balls of the first type, removing the stencil mask; and
after removing the stencil mask, disposing electrically conductive balls of the second type into the through-holes of the stencil into which electrically conductive balls of the first type have not been disposed.

12. A semiconductor package comprising:
a substrate or integrated circuit (IC) chip having electrical bonding pads disposed on a surface of the substrate or IC chip;
a second substrate or IC chip; and
a ball grid array (BGA) electrically and mechanically connecting the surface of the substrate or IC chip to the second substrate or IC chip, the BGA including:
electrically conductive balls bonded to the electrical bonding pads of the surface of the substrate or IC chip and to the second substrate or IC chip; and
underfill material disposed on the surface of the substrate or IC chip around bonds between the electrically conductive balls and the electrical bonding pads of the surface of the substrate or IC chip.

13. The semiconductor package of claim 12 wherein the electrically conductive balls of the BGA include:
electrically conductive balls of a first type comprising a solder ball without a core of copper or copper alloy; and
electrically conductive balls of a second type consisting of a copper or copper alloy or comprising a core of copper or copper alloy coated with a coating.

14. The semiconductor package of claim 13 wherein:
the electrically conductive balls of the first type are disposed in a peripheral region of the surface of the substrate or IC chip; and
the electrically conductive balls of the second type are disposed in a central region of the surface of the substrate or IC chip that is surrounded by the peripheral region.

15. The semiconductor package of claim 12 wherein the underfill material disposed around the bonds between the electrically conductive balls and the electrical bonding pads of the surface of the substrate or IC chip form annuluses of the underfill material encircling the respective bonds.

16. The semiconductor package of claim 15 wherein the annuluses of the underfill material do not completely cover the respective electrically conductive balls.

17. The semiconductor package of claim 15 wherein the annuluses of the underfill material have heights in a range of 20% and 90% of a diameter of the electrically conductive balls and the annuluses of the underfill material extend away from the respective bonds along the surface of the substrate or IC chip a distance that is in a range of 20% and 90% of a diameter of the electrically conductive ball.

18. A semiconductor package comprising:
a substrate or integrated circuit (IC) chip having electrical bonding pads disposed on a surface of the substrate or IC chip;
a second substrate or IC chip; and
a ball grid array (BGA) electrically and mechanically connecting the surface of the substrate or IC chip to the second substrate or IC chip, the BGA including electrically conductive balls of at least two different types.

19. The semiconductor package of claim 18 wherein the electrically conductive balls of at least two different types include:
a first type of electrically conductive ball comprising a solder ball without a core of copper or copper alloy; and
a second type of electrically conductive ball consisting of a copper or copper alloy or comprising a core of copper or copper alloy coated with a coating.

20. The semiconductor package of claim 19 wherein:
the electrically conductive balls of the first type are disposed in a peripheral region of the surface of the substrate or IC chip, and
the electrically conductive balls of the second type are disposed in a central region of the surface of the substrate or IC chip that is surrounded by the peripheral region.
